(19) United States
(12) Patent Application Publication
(10) Pub. No.: US 2026/0254230 A1
(43) Pub. Date: Aug. 27, 2026

(54) METHOD FOR BALANCING, A BALANCING CIRCUIT AND AN INSULATION MONITORING DEVICE FOR AN UNGROUNDED DIRECT-VOLTAGE POWER SUPPLY SYSTEM

(71) Applicant: Bender GmbH & Co. KG, Gruenberg (DE)

(72) Inventor: Dieter Hackl, Fernwald (DE)

(21) Appl. No.: 19/542,867

(22) Filed: Feb. 18, 2026

(30) Foreign Application Priority Data
Feb. 24, 2025 (DE) 10 2025 106 867.4

(51) Int. Cl. H02H 9/08; G01R 31/14; G01R 31/52

(52) U.S. Cl. CPC H02H 9/08; G01R 31/14; G01R 31/52

(57) ABSTRACT

A method and a balancing circuit (10) for balancing an ungrounded direct-voltage power supply system (2) are disclosed. In a detector circuit (12), a faulty active conductor (L-) is detected in which a largest leakage current to ground (PE) flows because of a lowest insulation resistance (R_{f}₋). The faulty active conductor (L-) is coupled to the balancing circuit (10) by means of a switching device (14), the largest leakage current being compensated by means of an open-loop and closed-loop control device (16) of the balancing circuit (10) without reducing the insulation resistance (R_{f+}) of the other active conductor (L+). Furthermore, an enhanced insulation monitoring device (30) is provided for monitoring an ungrounded direct-voltage power supply system having a balancing circuit (10).

This application claims the benefit of German patent application no. 10 2025 106 867.4, filed Feb. 24, 2025, the disclosure of which is incorporated herein by reference.

### TECHNICAL FIELD

The invention relates to a method for balancing, a balancing circuit for an ungrounded direct-voltage power supply system having active conductors, which each have an insulation resistance to ground.

### BACKGROUND

Furthermore, the invention relates to an insulation monitoring device having the balancing circuit according to the invention.

When there are increased requirements for the operational, fire, and touch safety of electrical systems, an ungrounded power supply system is used, which is also referred to as an isolated network (French: "Isolé Terre"—IT network) or an IT power supply system. In this type of power supply system, the active parts of the power supply system are isolated from the ground potential—to ground. The parts of the connected electrical consumers are grounded individually or collectively. The advantage of these networks is that, in the event of a first insulation fault, the operability of the connected electrical consumers is not impaired and operation can therefore continue despite the faulty condition of the insulation, as no closed (fault) circuit can form due to the ideally infinitely large electrical resistance between an active conductor of the network and ground potential.

In the context of this invention, insulation resistance is understood to be the ohmic component of a complex insulation impedance. The ohmic current component flowing through this insulation resistance is referred to as leakage current.

Since a possible further (insulation) fault on another active conductor would result in a fault loop and the fault current flowing in conjunction with an overcurrent protection device would cause the system to shut down and come to a standstill, the insulation resistance of the ungrounded power supply system must be constantly monitored using an insulation monitoring device (IMD).

Ungrounded power supply systems are therefore mainly used in applications where an automatic shutdown of the power supply in the event of a first insulation fault would lead to undesirable risks and hazards. Continuing to operate the power supply until the insulation fault has been eliminated is therefore a desirable and advantageous approach for the system operator.

When a first insulation fault occurs, a conductor-to-ground voltage (voltage between one of the active conductors and ground) equal to the conductor-to-conductor amplitude (conductor voltage) may occur on the connected operating equipment until the insulation fault is eliminated. This voltage surge must be taken into account in the insulation coordination for operating equipment operated in an IT system.

However, with the increasing prevalence of direct-voltage power supply systems with the IT system as the ungrounded network configuration, there are also increasingly varying requirements and operating modes.

For example, industrial direct-voltage power supply systems require operating equipment which is readily available and can be used cost-effectively in grounded power supply systems to also be used unchanged in direct-voltage power supply systems with the IT system as the ungrounded network configuration. However, in the event of continuous unbalanced operation of the ungrounded power supply to ground, the creepage distances of the connected operating equipment could be overloaded as a result of voltage shift with a displacement voltage as a signed voltage difference to the center point voltage and the resulting voltage surge at the individual active conductors, and the operating equipment could fail prematurely.

In the course of the shift towards electromobility, the electrical safety of DC charging stations is becoming particularly important. These applications often involve publicly accessible power supplies which are operated as IT systems with high voltages and very high performances. The product standard IEC 61581-23 therefore also takes into account the case of a person touching an active conductor and the discharge of radio safety capacitors via a person as part of the protective measures against electric shock. Since the energy content of capacitors increases quadratically with voltage, larger Y radio interference suppression capacitors can be used in DC charging stations if the voltage at these capacitors can be minimized by balancing the IT system to ground.

According to the known state of the art, passive balancing in DC IT systems is achieved by setting an insulation fault of the faulty active conductor to ground by means of an open-loop or closed-loop control of the ohmic leakage of the other (non-faulty) active conductor, i.e., the active conductor with opposite polarity, to ground, in such a manner that sufficient balancing of the conductor-to-ground voltages is achieved.

Patent specification DE10 2018116055 B3 shows a method and insulation monitor for resistance-adaptive insulation monitoring, in which a combination of a semiconductor switch and resistance is modulated to form a coupling resistance which remains constant over a certain integration time, thereby enabling the direct-voltage network to be balanced.

In addition, the current state of the art follows the approach to actively balance the ungrounded DC power supply system when the insulation condition is sufficiently high-impedance or, in the event of a first low-impedance fault which cannot be balanced with the existing measures, to shut down the faulty branch.

Patent application document DE10 2018211625 A1 describes an on-board supply system arrangement having a balance monitoring device for a motor vehicle, the insulation resistances being able to be balanced in a compensation device with power sources and variable resistances.

Furthermore, patent application document WO2023/007253A1 discloses a network-balancing insulation monitoring device with active voltage-unbalance correction. Analogously controllable voltage-source and power-source circuits are used for this purpose, although these result in an extremely complex circuit design.

In DC charging stations, however, active balancing which is not integrated into an insulation monitoring system carries the risk that the reduced total insulation resistance will lead to premature shutdown of the DC charging station.

In the case of active balancing which is integrated in an insulation monitoring system of DC charging stations, the reduced total insulation resistance can lead to an increased touch current in the event of physical contact.

The state of the art in ungrounded DC IT systems is therefore characterized by the fact that an ohmic leakage on an active conductor is introduced by a suitable ohmic leakage on the active conductor with opposite polarity to ground.

In ungrounded AC IT systems, it is state of the art to provide the system with sufficiently large network leakage capacitances distributed evenly across all active conductors to ground.

A disadvantage of the known method is the reduction of the total insulation level (total insulation resistance) of the ungrounded DC power supply system to ground. In industrial ungrounded DC power supply systems, this increases the risk of corrosion-effective DC leakage occurring and negatively affecting insulation monitoring.

Even with ungrounded alternating-voltage power supply systems, there are applications in which balanced operation to ground is desirable. In alternating-voltage power supply systems with larger network leakage capacitances, balancing to ground is achieved solely through evenly distributed network leakage capacitances. Applications in which this cannot be guaranteed can be covered by the invention at hand.

### SUMMARY

The object of the invention at hand is therefore to design a method and a circuit for balancing an ungrounded power supply system, in particular a direct-voltage power supply system, without reducing the total insulation resistance of the ungrounded power supply system.

This task is solved by a balancing method with the following method steps: detecting a faulty active conductor in which a largest leakage current to ground flows because of a lowest insulation resistance; coupling this faulty active conductor to a balancing circuit, which is switched between the faulty active conductor and ground; compensating the largest leakage current by means of an open-loop and closed-loop control device of the balancing circuit, the insulation resistance of the other active conductor not being reduced.

Furthermore, the object is attained by a balancing circuit having a detector circuit for detecting a faulty active conductor in which a largest leakage current flows to ground because of a lowest insulation resistance; a switching device for coupling this faulty active conductor to the balancing circuit, which is switched between the faulty active conductor and ground; and an open-loop and closed-loop control device, which is configured for compensating the largest leakage current, the insulation resistance of the other active conductor not being reduced.

The claimed balancing method is based on the fundamental idea that compensatory action is taken directly at the active conductor having the lowest insulation resistance, i.e., the conductor through which the largest leakage current to ground flows, thereby completely or partially balancing this (largest) leakage current at the active conductor in question in order to adjust the conductor-to-ground voltages of the active conductors of the IT system as balanced as possible to ground.

After the active conductor having the lowest insulation resistance has been determined by means of a detector circuit and the balancing circuit has been switched between the thus detected active conductor having the lowest insulation resistance and ground by means of a switching device, the leakage current flowing from the active conductor to ground is compensated by an open-loop and closed-loop control device. The open-loop and closed-loop control device forms the main component of the balancing circuit and has a controllable component, such as a negative resistance, a voltage-controlled power source, a PWM signal generator, or a correction capacitor, to compensate for the leakage current by means of open-loop or closed-loop adjustment.

Since, in contrast to the state of the art, the leakage current of the other active conductor to ground is not affected, in particular not increased, i.e., the insulation resistance of the other active conductor and thus also the total insulation resistance of the ungrounded power supply system is not reduced, this approach can be used to advantageously to both balance voltage and increase the total insulation resistance at the same time.

In a further design, the faulty active conductor is detected using the lowest insulation resistance by capturing and evaluating a displacement voltage.

The occurrence of an insulation fault on one of the active conductors manifests itself in a voltage unbalance of the conductor-to-ground voltages (voltage of the corresponding active conductor to ground). A displacement voltage occurs, which is detected and evaluated in terms of magnitude and sign, and from this, the active conductor having the lowest insulation resistance (faulty active conductor) in a detector circuit can be determined.

As an alternative to detecting and evaluating the displacement voltage, the faulty active conductor is detected using the lowest insulation resistance by evaluating information on the conductor-related insulation resistances.

In cases where information on conductor-related insulation resistances (i.e., those assigned to individual active conductors) is already available—computed, for example, by an insulation monitoring device or by means of internal computations in the balancing circuit—the detector circuit evaluates the conductor-related insulation resistances transmitted to it or computed itself in order to determine the active conductor having the lowest insulation resistance.

Preferably, the largest leakage current in the open-loop and closed-loop control device is compensated by an open-loop or closed-loop adjustment of a voltage-controlled, electronically generated negative resistance.

In this design, the open-loop and closed-loop control device has a voltage-controlled negative resistance as an active semiconductor structural element, the negative resistance compensating the (lowest) insulation resistance of the faulty active conductor.

Alternatively, the largest leakage current in the open-loop and closed loop control device is compensated by an open-loop or closed-loop adjustment of a voltage-controlled power source for generating a current flow having a polarity of the largest leakage current in phase opposition.

The compensation current in phase opposition generated by the voltage-controlled power source counteracts the largest leakage current, the voltage being balanced in conjunction with the open-loop and closed-loop control.

As a further alternative, the largest leakage current in the open-loop and closed-loop control device is compensated by an open-loop or closed-loop adjustment of a PWM signal generator for digitally generating a PWM compensation current signal having a polarity of the largest leakage current in phase opposition.

In contrast to continuously feeding the compensation current by means of the voltage-controlled power source, the largest leakage current is compensated in a time-discrete form by means of a PWM signal generator, which generates a PWM compensation current signal having polarity in phase opposition to compensate the largest leakage current. Various energy-saving switching regulator topologies, such as a high-frequency clocked flyback converter, can be used here.

The largest leakage current in the open-loop and closed-loop control device can also be compensated by an open-loop or closed-loop adjustment of a compensation capacitor for supplying an electrical capacitor charge having a polarity of the largest leakage current in phase opposition.

An example of this is the time-discrete feeding of a capacitor charge in phase opposition, e.g., with the aid of switching-capacitor charge pumps.

It is advantageous to a limit a compensation current flowing between the faulty active conductor and ground is limited.

If the required compensation current to be generated for balancing exceeds a value considered critical, the compensation current actually generated can be limited to a value considered uncritical by a limitation circuit, even if the voltage unbalance continues to increase.

Furthermore, in the compensated state, a compensation resistance is computed from a conductor-to-ground voltage of the faulty active conductor and a compensation current and in that the conductor-related insulation resistances are computed by taking into consideration a nominal voltage and the displacement voltage.

The balancing circuit can thus be designed to perform the function of an insulation monitoring device with determination of the conductor-related insulation resistances in addition to balancing.

The structural components claimed in the balancing circuit according to the invention perform the corresponding method steps of the method according to the invention for balancing the ungrounded direct-voltage power supply system. Thus, the technical effects achieved using the balancing method and the resulting advantages apply equally to the balancing circuit.

The present invention succeeds in balancing the conductor-to-ground voltages in an ungrounded direct-voltage power supply system by completely or partially compensating the (ohmic) leakage current to ground at the active conductor using the lowest insulation resistance without reducing the insulation resistance of the other conductors. The total insulation resistance of the ungrounded direct-voltage power supply system is thus not reduced in a manner advantageous in terms of safety and can be increased by the proposed measures.

If these measures are intended to balance ungrounded alternating-voltage power supply systems, the focus here is also on compensating unbalanced ohmic leakages to ground. The invention does not consider the compensation of unbalanced capacitive leakage currents.

The balancing circuit according to the invention can be used both as an autonomous structural unit for connection to an ungrounded direct-voltage power supply system and be integrated in an extended insulation monitoring device—preferably designed in accordance with the IEC 61557-8 standard—to form a structural unit.

### BRIEF DESCRIPTION OF DRAWINGS

Further advantageous design features are derived from the following description and the drawings, which describe a preferred embodiment of the invention using examples.

FIG. 1 shows an ungrounded direct-voltage power supply system with insulation monitoring and a balancing circuit according to the invention.

FIG. 2 shows the arrangement from FIG. 1 with a detailed balancing circuit.

FIG. 3 shows a simulation arrangement for FIG. 2 with a deactivated balancing circuit and use of a negative resistance (open-loop control).

FIG. 4 shows a simulation arrangement for FIG. 2 with an activated balancing circuit and usage of a negative resistance (open-loop control).

FIG. 5 shows a simulation arrangement for FIG. 2 with an activated balancing circuit and usage of a negative resistance (closed-loop control).

### DETAILED DESCRIPTION

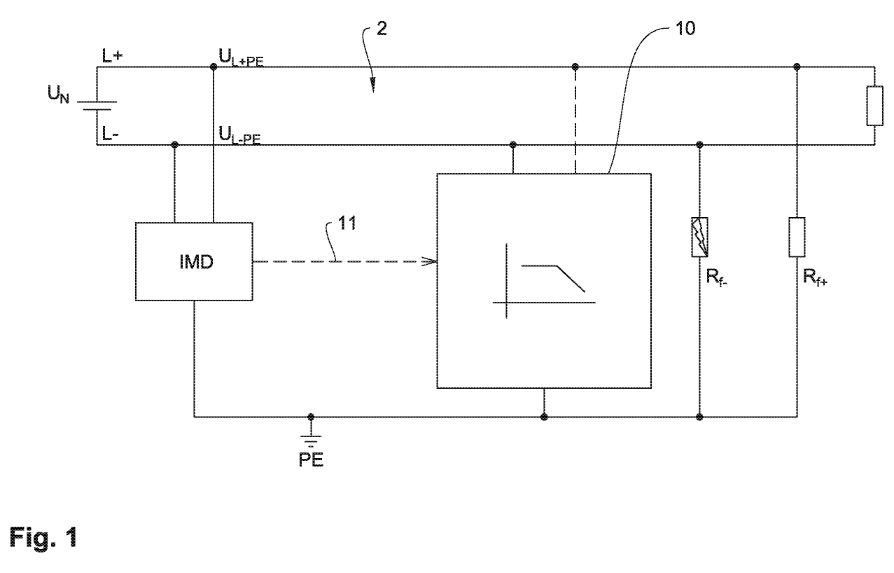

FIG. 1 shows an ungrounded direct-voltage power supply system 2 with two active conductors L+, L-, which is supplied by the nominal voltage U_{N} and monitored by an insulation monitoring device IMD.

The active conductors L+, L- conduct the corresponding conductor-to-ground voltages U_{L+PE}, U_{L-PE} to ground PE, the conductor-to-ground voltages U_{L+PE,} U_{L-PE} having the same magnitude under a balanced load. The occurrence of an unbalanced insulation fault, represented here by the (lowest) insulation resistance R_{f-} at the negative active conductor L-, leads to a voltage unbalance between the conductor-to-ground voltages U_{L+PE} and U_{L-PE}. To compensate this voltage unbalance, the balancing circuit 10 according to the invention is coupled to the active conductor L+, L- which has the lowest insulation resistance R _{f-}, in this case to the conductor L- having the lowest insulation resistance R_{f-} determined by the resistive insulation fault.

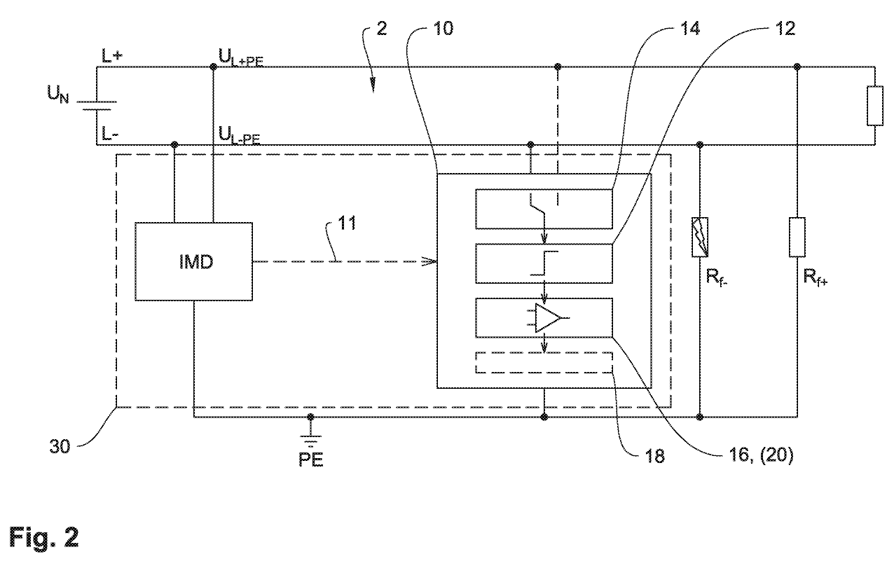

FIG. 2 shows the arrangement from FIG. 1 having an ungrounded direct-voltage power supply system 2, insulation monitoring device IMD, and the balancing circuit 10 in detail.

The balancing circuit 10 comprises a detector circuit 12, which is designed as a voltage-measuring and evaluation device and detects a displacement voltage in conjunction with a switching device 14. The displacement voltage is evaluated in terms of magnitude and sign in order to detect the faulty active conductor—in this case conductor L- having the (lowest) insulation resistance R_{f-}—and thus the leakage branch having the largest leakage current.

If information 11 on the magnitude of the conductor-related insulation resistances R_{f+}, R_{f-} is already available (because the conductor-related insulation resistances R_{f+}, R_{f-} have already been determined, for example, in an insulation monitoring device IMD), the detector circuit 12 is configured for evaluating existing information 11 on the conductor-related insulation resistances R_{f+}, R_{f-} as an alternative to the voltage-measuring and evaluation device.

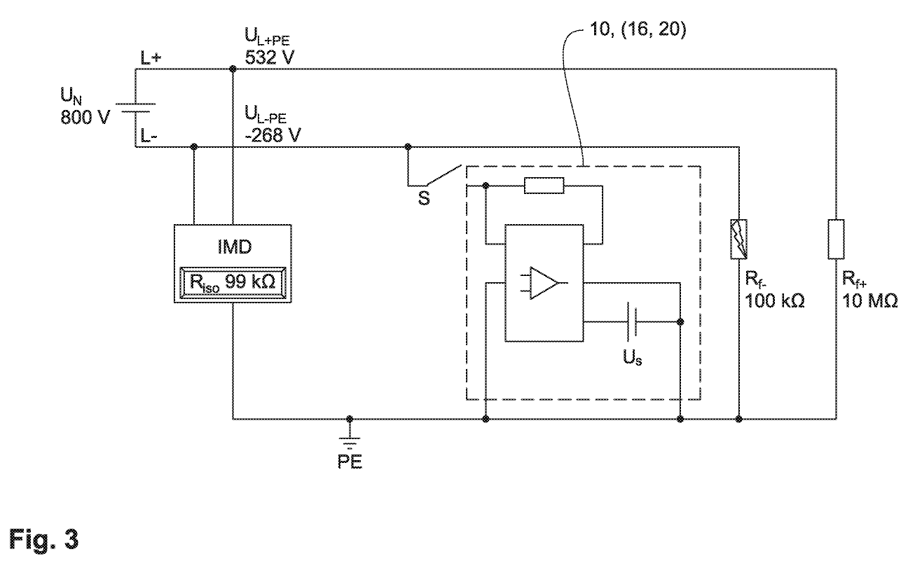

An essential component of the balancing circuit 10 is an open-loop and closed-loop control device 16, which performs the actual compensation of the largest leakage current and thus the lowest insulation resistance R_{f-}. The open-loop and closed-loop control device 16 can alternatively have a negative resistance 20 (FIG. 3), a voltage-controlled power source, a PWM signal generator or a compensation capacitor for each case.

The balancing circuit 10 may also comprise a limitation circuit 18 which limits a compensation current Iₖ to a maximally permissible value.

The balancing circuit 10 can also perform the insulation monitoring function by detecting the nominal voltage U_{N}, the displacement voltage and the compensation current Iₖ in the compensated state and using these values to compute the conductor-related insulation resistances R_{f+} and R_{f-}. A separate insulation monitoring device IMD is then not necessary.

On the other hand, the balancing circuit 10 according to the invention can be combined with the insulation monitoring device IMD to form an extended insulation monitoring device 30 in the form of a structural unit.

The following illustrations in FIGS. 3 to 5 illustrate the effectiveness of the balancing method according to the invention and the mode of operation of the balancing circuit according to the invention, which executes this method, on the basis of simulations of the insulation-monitored and ungrounded direct-voltage power supply system 2 to be balanced.

FIG. 3 shows, as an exemplary embodiment, a simulation arrangement corresponding to FIG. 2 and having an initially deactivated balancing circuit 10, using a voltage-controlled negative resistance 20 in the open-loop and closed-loop control device 16 of the balancing circuit 10.

The active conductor L- (minus conductor) has an insulation fault simulated by the (lowest) insulation resistance R_{f-} = 100 kΩ, whereas the other active conductor L+ (plus conductor) has an uncritical insulation resistance R_{f+} = 10 MΩ.

When the balancing circuit 10 is deactivated the unbalanced load results in a conductor-to-ground voltage U_{L+PE} = 532 V at the positive conductor L+ and a conductor-to-ground voltage U_{L-PE} = -268 V at the negative conductor L- based on a nominal voltage U_{N} = 800 V. The displacement voltage is therefore 132 V (in terms of magnitude) and, in practical implementation, its magnitude and sign can be detected and evaluated by a detector circuit 12 designed as a voltage-measuring and evaluation device to determine the active conductor having the lowest insulation resistance R_{f-}.

Since the simulation is intended to demonstrate the effectiveness of compensation in the leakage branch of the lowest insulation resistance R_{f–}, the faulty minus conductor L- and, for control purposes, the control voltage Uₛ of the negative resistance 20, which is implemented in the simulation by an adjustable voltage source, are specified. This eliminates the necessity for the detector circuit 12 (FIG. 2) and the switching device 14 (FIG. 2) in the simulation arrangement; the switch S for activating the voltage-controlled negative resistance 20 is open.

In a compensated state with a voltage-controlled negative resistance 20, R_{f-} = -R_{comp} applies to the insulation resistance R_{f-} of the negative conductor L and the compensation resistance. With the formation of a voltage coefficient Kᵤ from the displacement voltage and the nominal voltage U_{N}, the insulation resistance R_{f+} of the positive conductor L+ can be computed as R_{f+} = (R_{f-}/(1/2 Kᵤ )) – R_{f-}.

The simulated insulation monitoring device IMD determines a total insulation resistance Rᵢₛₒ= 99 kΩ. This correctly corresponds to the parallel circuit of R_{f-} = 100 kΩ and R_{f+} = 100 MΩ.

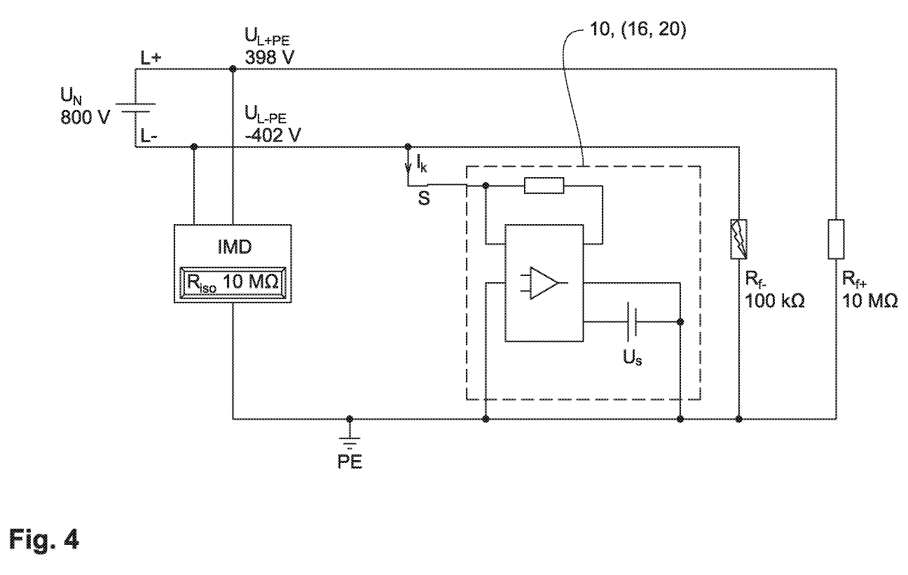

In FIG. 4, the switch S for activating the voltage-controlled negative resistance 20 is closed, so that the compensation takes effect.

At a displacement voltage of (in terms of magnitude) 2 V, there is almost complete balance between the conductor-to-ground voltages U_{L+PE} = 398V and U_{L-PE} = -402 V.

The simulated insulation monitoring device IMD determines a total insulation resistance Rᵢₛₒ = 10 MΩ. This corresponds to the insulation resistance of 10 MΩ between the positive conductor L+ and ground PE.

The insulation fault R_{f-} = 100 kΩ between the negative conductor L- and ground PE is thus compensated.

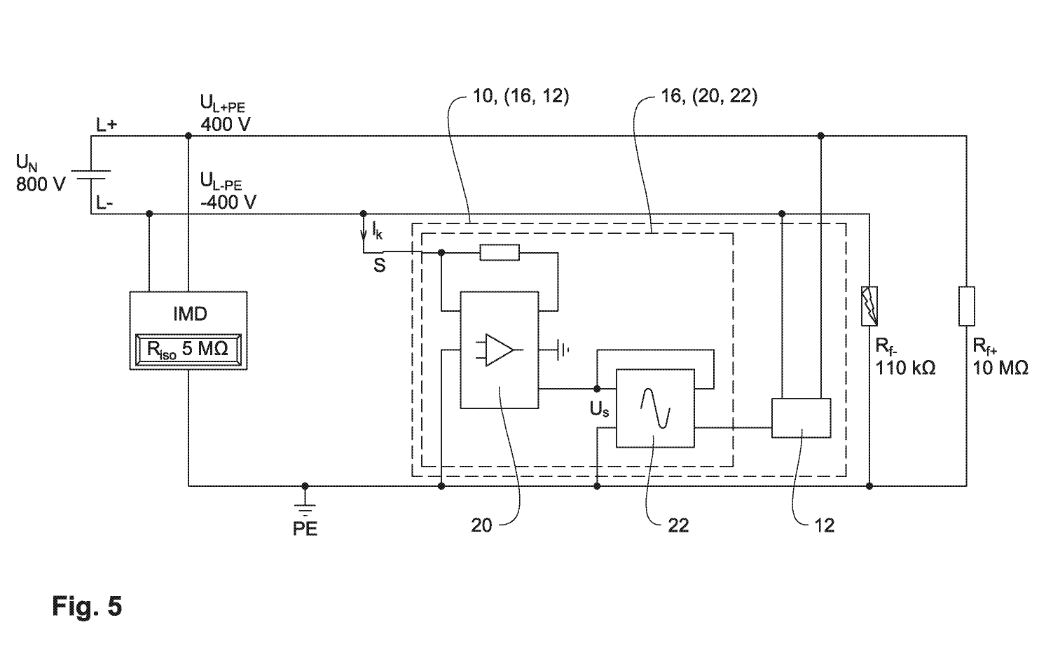

FIG. 5 shows, as a further exemplary embodiment, a simulation arrangement corresponding to FIG. 2 with (active) balancing circuit 10 in the form of an open-loop and closed-loop control device 16 designed as a control system and having a detector circuit 12 designed as a voltage-measuring and evaluation device for determining the displacement voltage.

The open-loop and closed-loop control device 16 comprises a voltage-controlled negative resistance 20 and a controlled voltage source 22 for supplying the control voltage Uₛ to the voltage-controlled negative resistance 20. The controlled voltage source 22 receives the displacement voltage determined by the detector circuit 12 as an input parameter indicating unbalance and provides a control voltage Uₛ derived from the detector circuit 12 as a variable for the open-loop control circuit on the output side. Instead of the switching device 14 present in a practical implementation, the coupling of the balancing circuit 10 in the simulation is manually specified by the closed switch S. The insulation fault at the negative conductor L- is modeled by the insulation resistance R_{f}₋ = 110 kΩ.

The control system automatically balances the conductor-to-ground voltages U_{L+PE} and U_{L-PE} to the values U_{L+PE} = 400 V and U_{L-PE} = -400 V.

In this case, the simulated insulation monitoring device IMD detects an outwardly effective total insulation resistance of Rᵢₛₒ = 5 MΩ.

1. A method for balancing an ungrounded direct-voltage power supply system (2) having active conductors (L+, L-) which each have an insulation resistance (R_{f+} R_{f}_{–}) to ground (PE), the method comprising the following steps:
detecting a faulty active conductor (L-) in which a largest leakage current to ground (PE) flows because of a lowest insulation resistance (R_{f}_{–}),
coupling this faulty active conductor (L-) to a balancing circuit (10), which is switched between the faulty active conductor (L-) and ground (PE),
compensating the largest leakage current by means of an open-loop and closed-loop control device (16) of the balancing circuit (10), the insulation resistance (R_{f+}) of the other active conductor (L+) not being reduced.

2. The balancing method according to claim 1, wherein
the faulty active conductor (L-) is detected using the lowest insulation resistance (R_{f–}) by capturing and evaluating a displacement voltage.

3. The balancing method according to claim 1, wherein
the faulty active conductor (L-) is detected using the lowest insulation resistance (R_{f–}) by evaluating information (11) on the conductor-related insulation resistances (R_{f+} R_{f–}).

4. The balancing method according to claim 1, wherein
the largest leakage current in the open-loop and closed-loop control device (16) is compensated by an open-loop or closed-loop adjustment of a voltage-controlled, electronically generated negative resistance (20).

5. The balancing method according to claim 1, wherein
the largest leakage current in the open-loop and closed loop control device (16) is compensated by an open-loop or closed-loop adjustment of a voltage-controlled power source for generating a current flow having a polarity of the largest leakage current in phase opposition.

6. The balancing method according to claim 1, wherein
the largest leakage current in the open-loop and closed-loop control device (16) is compensated by an open-loop or closed-loop adjustment of a PWM signal generator for digitally generating a PWM compensation current signal having a polarity of the largest leakage current in phase opposition.

7. The balancing method according to claim 1, wherein the largest leakage current in the open-loop and closed-loop control device is compensated by an open-loop or closed-loop adjustment of a correction capacitor for supplying an electrical capacitor charge having a polarity of the largest leakage current in phase opposition.

8. The balancing method according to claim 1, wherein
a compensation current (Iₖ) flowing between the faulty active conductor (L_{–}) and ground is limited.

9. The balancing method according to claim 2,wherein
in the compensated state, a compensation resistance is computed from a conductor-to-ground voltage (U_{L–PE}) of the faulty active conductor (L_{–}) and a compensation current (Iₖ) and in that the conductor-related insulation resistances (R_{f+} R_{f–}) are computed by taking into consideration a nominal voltage (U_{N}) and the displacement voltage.

10. A balancing circuit (10) for balancing an ungrounded direct-voltage power supply system (2) having active conductors (L+, L-) which each have an insulation resistance (R_{f+} R_{f–}) to ground,
wherein
a detector circuit (12) for detecting a faulty active conductor (L-) in which a largest leakage current flows to ground (PE) because of a lowest insulation resistance (R_{f–}),
a switching device (14) for coupling this faulty active conductor (L-) to the balancing circuit (10), which is switched between the faulty active conductor (L-) and ground (PE), and
an open-loop and closed-loop control device (16), which is configured for compensating the largest leakage current, the insulation resistance (R_{f+}) of the other active conductor (L+) not being reduced.

11. The balancing circuit (10) according to claim 10, wherein
the detector circuit (12) is designed as a voltage-measuring and evaluation device for capturing and evaluating a displacement voltage.

12. The balancing circuit (10) according to claim 10, wherein
the detector circuit (12) is designed for evaluating information (11) on the conductor-related insulation resistances (R_{f+} R_{f–}).

13. The balancing circuit (10) according to claim 10, wherein
the open-loop and closed-loop control device (16) is configured for the open-loop or closed-loop adjustment of a voltage-controlled, electronically generated negative resistance (20).

14. The balancing circuit (10) according to claim 10, wherein
the open-loop and closed-loop control device (16) is configured for the open-loop or closed-loop adjustment of a voltage-controlled power source in order to generate a current flow having a polarity of the largest leakage current in phase opposition.

15. The balancing current (10) according to claim 10, wherein
the open-loop and closed-loop control device (16) is configured for the open-loop or closed-loop adjustment of a PWM signal generator in order to generate a PWM compensation current signal having a polarity of the largest leakage current in phase opposition.

16. The balancing circuit (10) according to claim 10, wherein
the open-loop and closed-loop control device (16) is configured for the open-loop or closed-loop adjustment of a correction capacitor in order to generate an electrical capacitor charge having a polarity of the largest leakage current in phase opposition.

17. The balancing circuit (10) according to claim 10, comprising:
a limitation circuit (18) for limiting a compensation current (Iₖ) flowing between the faulty active conductor (L-) and ground (PE).

18. The balancing circuit (10) according to claim 10, comprising:
a design for computing a compensation resistance from a conductor-to-ground voltage (U_{L–PE}) of the faulty active conductor (L-) and a compensation current (Iₖ) and for computing the conductor-related insulation resistances (R_{f+} R_{f–}) taking into account a nominal voltage (U_{N}) and the displacement voltage in a compensated state.

19. The balancing circuit (10) according to claim 10, comprising:
a configuration as an autonomous structural unit.

20. An enhanced insulation monitoring device (30) for monitoring an ungrounded direct-voltage power supply system, the enhanced insulation monitoring device (30) having an insulation monitoring device (IMD) and a balancing circuit (10) according to claim 10, integrated in a structural unit.
